(19) United States
(12) Patent Application Publication
(10) Pub. No.: US 2024/0357742 A1
(43) Pub. Date: Oct. 24, 2024

(54) PRINTED PRODUCT, PREPARATION METHOD THEREFOR, AND USE THEREOF

(71) Applicant: Heraeus Electronics GmbH & Co. KG, HANAU (DE)

(72) Inventors: Shouming AN, SHANGHAI (CN); Rong WANG, SHANGHAI (CN); Erwei LIU, SHANGHAI (CN); Fangzhong SHEN, Changshu (CN)

(21) Appl. No.: 18/686,287

(22) PCT Filed: Aug. 30, 2022
(86) PCT No.: PCT/EP2022/025400

§ 371 Date: Feb. 23, 2024

(30) Foreign Application Priority Data
Aug. 30, 2021 (CN) 202111029060.2

(51) Int. Cl. H05K 1/09

(52) U.S. Cl. CPC H05K 1/097

(57) ABSTRACT

A printed product, which comprises: a. a substrate; b. a primer layer located on the substrate, wherein the primer layer comprises an organic dielectric material; c. a metal conductive layer located on the primer layer; wherein the printed product further comprises a hybrid layer between the primer layer and the metal conductive layer, wherein the hybrid layer comprises materials from the primer layer and the metal conductive layer. In addition, the present invention further relates to a method for preparing the printed product and an electronic device comprising the printed product. The metal conductive layer in the printed product of the present invention has excellent uniformity in thickness; good adhesion between the primer layer and the conductive layer; and the printed product of the present invention has excellent EMI shielding effects, such that the printed product can be used in high frequency applications such as 5G applications.

### TECHNICAL FIELD

The present invention relates to a printed product. In addition, the present invention further relates to a method for preparing the printed product and an electronic device comprising the printed product.

### BACKGROUND

Electromagnetic interference (EMI) may generate current pulses in electronic devices, thereby affecting the normal operation of the electronic devices. Therefore, EMI shielding is often required. With the miniaturization of electronic products and the increasing demand for high-speed computing electronic components, protection against EMI is also increasingly important. In addition, the thermal conductivity of electronic devices is also important.

A conventional method for EMI shielding and thermal conduction of printed circuit board assemblies (PCBAs) and flexible printed circuit boards (FPCBs) for consumer electronic devices is a shielding can with a thermally conductive interface material (TIM) inside. The main disadvantages thereof are low EMI shielding performance in the 5G frequency range; poor thermal conductivity; for FPCBs for foldable devices, it is impossible to achieve a good balance between bending performance and EMI performance; and for small devices, the space/thickness of the shielding can is overly large. In addition, the adhesion between a backplane and a metal layer for EMI shielding is poor.

Using a silver film on an electromagnetic compatibility component (EMC) as an example, the adhesion is mainly determined by mechanical contact or electrical absorption, and therefore, the thermal expansion coefficient (CTE) of the EMC, the hardness of the EMC, the roughness of the EMC, and a silver deposition process are all important factors. In the prior art, surface processing is performed first, and the EMC surface is ground to obtain a proper roughness and is then coated with a conductive ink. The disadvantages thereof are: adhesion caused by mechanical contact or electrical absorption depends on many factors, such as those mentioned above, resulting in poor reliability in reliability testing; mostly unsuitable for various electronic components; a few methods can be widely used in various electronic components, but require change of the surface topography (i.e., grinding), which is not allowed by users and is not suitable for large-scale industrial production; conductive inks containing adhesives are poor in electrical conductivity after being cured or sintered.

For example, US 2013/0286609 A1 discloses a method for forming a conformal electromagnetic interference shield, including: processing a portion of a printed circuit board for adhering an insulating layer; applying the insulating layer on the processed portion; processing at least one of the applied insulating layer and a perimeter for adhering with a conductive layer; placing the conductive layer on at least one of the processed insulating layer and the perimeter, where the conductive layer is formed by inkjet printing or physical vapor deposition (PVD).

KR101823134B1 discloses an ink for forming a shielding cover, a method for manufacturing a shielding cover by a 3D printing method using the ink, and a shielding cover prepared by the method, the ink comprising 10-30 parts by weight of an epoxy acrylate, 10-30 parts by weight of a chlorinated polyester acrylate, 30-50 parts by weight of silver-plated copper particles, and 25-30 parts by weight of silver-plated glass particles.

CN 101036424 A discloses a method for manufacturing a printed circuit board using liquid electrophotographic printing, including: printing a first layer of conductive ink traces on a medium; printing at least one region of a dielectric ink on at least one printed trace; printing a second layer of conductive traces on the first layer on the substrate, the dielectric ink insulating at least a portion of the second layer from the first layer. The method is used to form conductive traces on the substrate, and does not involve an electromagnetic interference shielding layer; furthermore, the ink used comprises metal nanoparticles selected from copper, gold, silver, and platinum.

U.S. Pat. No. 8,283,577 B2 discloses a printed product, including: a substrate; a primer layer located on the substrate; and a functional ink layer formed on the primer layer in a predetermined pattern, wherein the thickness of the primer layer at a pattern-forming portion where the functional ink layer is formed in the predetermined pattern is greater than the thickness of the primer layer at a non-pattern forming portion where the functional ink layer is not formed in the predetermined pattern. However, this patent only relates to a gravure printing method. According to the invention, in the primer layer formed on the substrate, the thickness of the primer layer at a pattern-forming portion where the functional ink layer is formed in the predetermined pattern is greater than the thickness of the primer layer at a non-pattern forming portion where the functional ink layer is not formed in the predetermined pattern. Thus, for example, when the printed product of the present invention is manufactured using the gravure printing method, the primer layer is provided to fill indentations. The primer layer having such a structure is formed by filling a gravure portion with dents in an upper part of the functional ink after scrape coating using a scraping blade or a wiping roller in the manufacturing process of the printed product. As a result, formed is a printed product in which the primer layer adheres to the functional ink without cavities therebetween, without problems such as broken lines, improper shapes, and low adhesion due to insufficient transfer of the functional ink. The patent states that during a transfer process, due to an upward movement of the primer, a mixed zone is created between the primer layer and the functional ink layer, thereby improving the adhesion therebetween.

However, there is still room for improvement in the adhesion between the conductive layer formed by the functional ink layer and the substrate in the document. In addition, gravure printing is used in the patent, and in order to form protrusions necessary in the gravure printing (i.e., the thickness of the primer layer at the pattern-forming portion where the functional ink layer is formed in the predetermined pattern is greater than the thickness of the primer layer at the non-pattern forming portion where the functional ink layer is not formed in the predetermined pattern), the printing ink used is required to have a high solid content and a high viscosity. This is not suitable for applications requiring high flatness, high thickness uniformity, and high electrical conductivity.

### SUMMARY

An objective of the present invention is to overcome the shortcomings of the prior art, to provide a printed product, which comprises:
a. a substrate;
b. a primer layer located on the substrate, wherein the primer layer comprises an organic dielectric material; and
c. a metal conductive layer located on the primer layer;
   wherein the printed product further comprises a hybrid layer between the primer layer and the metal conductive layer, wherein the hybrid layer comprises materials from the primer layer and the metal conductive layer.

Another objective of the present invention is to provide a method for manufacturing the above printed product, comprising:
1) providing a substrate;
2) applying a primer layer precursor on the substrate;
3) in a first cycle, applying a MOD ink sublayer on the primer layer precursor while the primer layer precursor is not fully cured;
4) co-curing the layers obtained from steps 2) and 3);
5) optionally, in one or more subsequent cycles, applying one or more other ink sublayers and curing the ink sublayer; and
6) annealing a resulting product.

Still another objective of the present invention is to provide an electronic device comprising the above printed product.

### DETAILED DESCRIPTION

### Printed Product

In one aspect of the present invention, the present invention provides a printed product, which comprises:
a. a substrate;
b. a primer layer located on the substrate, wherein the primer layer comprises an organic dielectric material; and
c. a metal conductive layer located on the primer layer;
   wherein the printed product further comprises a hybrid layer between the primer layer and the metal conductive layer, wherein the hybrid layer comprises materials from the primer layer and the metal conductive layer.

### Substrate

The substrate of the present invention can be any substrate that requires metallization, especially elements that require high surface conductivity such as ceramic filter elements, and other elements that require EMI shielding, including but not limited to PCBs (e.g., FPCBs), EMI shielding elements, antennas, capacitive touch sensors, conductive lines, chips, etc.

In particular, substrates usable in the present invention have a surface and the surface comprises at least one material selected from polymers, metals, ceramics, glass, and mixtures thereof (e.g., resin molding compounds, especially epoxy molding compounds, especially glass fiber-filled epoxy resins). In particular, the substrate has grooves on the surface.

### Primer Layer

The printed product of the present invention includes a primer layer located on the substrate, wherein the primer layer comprises an organic dielectric material. In particular, the organic dielectric material may be a polymer resin.

A primer layer precursor for forming the primer layer can be any coating composition capable of producing good adhesion on the surface of an electronic element, such as, but not limited to:
a carbon-based coating composition;
a silicon-based coating composition; and
a carbon-silicon mixed coating composition.

Usable carbon-based coating compositions may comprise film-forming components such as epoxy resins, polyimides, polyurethanes, alkyd resins, phenolic resins, acrylic resins, polyester resins, etc. Usable silicone-based coating compositions may comprise polysiloxane resins as film-forming components. Usable carbon-silicon mixed coating compositions may comprise carbon-based film-forming components selected from epoxy resins, polyimides, polyurethanes, alkyd resins, phenolic resins, acrylic resins, and polyester resins, and polysiloxane film-forming components.

The coating composition used may comprise a photopolymerization initiator, for example, benzophenone-based, acetophenone-based, thioxanthone-based, and benzoin-based compounds etc. may be used.

The coating composition used may further comprise a suitable additive. As additives, heat stabilizers, radical scavengers, plasticizers, surfactants, antistatic agents, antioxidants, ultraviolet absorbers, colorants, etc. may be used.

The coating composition may be applied to the substrate by using a suitable method, for example, by spray coating, spin coating, dip coating, dispensing, slot coating, or printing, preferably by screen printing or inkjet printing, more preferably by inkjet printing.

The coating composition may be applied in multiple passes, e.g., 1-20 passes. The thickness of the primer layer is not particularly limited and may be up to millimeter scale. The thickness of the primer layer may be adjusted according to the roughness of the surface of the substrate. Generally speaking, the rougher the surface is, the thicker the primer layer is required. The thickness of the primer layer may usually be 50-5000 nm, preferably 500-1000 nm.

The printed product may include a heat-generating device, such as a chip, a power device, etc., wherein the thickness of the primer layer on the heat-generating device is less than the thickness of the primer layer on at least a part of other regions, preferably the thickness of the primer layer on the heat-generating device is less than the thickness of the primer layer on all the other regions. In particular, the thickness of the primer layer on the heating device may be 50-5000 nm, preferably 100-500 nm. The other regions may be regions that include a passive device.

In one embodiment, the primer layer precursor may be simultaneously printed using one or more inkjet printing apparatuses at a certain angle (e.g., 1-90°, preferably 10-70°, more preferably 20-50°, particularly 45°) relative to the normal to the surface of the substrate (e.g., a PCB), such that the primer layer precursor can at least partially fill the grooves on the surface of the substrate, thereby reducing the waviness or roughness of the substrate surface, so as to planarize the surface of the substrate, thereby reducing the aspect ratio between parts in PCBA applications, reducing the shadow area, and increasing the coverage of the subsequent conductive layer, and additionally planarizing the surface with roughness, thereby achieving a better thickness and shielding uniformity.

The coating composition may be applied in a conformal or patterned manner. When the coating composition is applied in a patterned form, the coating composition is applied on a selected region of the substrate, while the other regions remain unapplied with the coating composition.

### Metal Conductive Layer

The metal conductive layer of the present invention may comprise metal or consist of a metal. The conductive layer has excellent electrical conductivity and thermal conductivity, so as to achieve the effects of EMI shielding and heat dissipation.

The metal conductive layer comprises a metal selected from Ag, Cu, Pt, Au, and Sn, or a combination thereof. The thickness of the metal conductive layer may be 0.5-1 μm, preferably 0.6-0.8 μm. The waviness or roughness of the surface of the substrate is higher than the waviness or roughness of the surface of the metal conductive layer.

The metal conductive layer precursor may be provided in the form of a MOD (metal-organic deposition) ink; or in the form of a metal particle-containing ink and a MOD ink, provided that a part of the metal conductive layer precursor that is immediately adjacent to the primer layer is provided in the form of the MOD ink.

The metal particle-containing ink may comprise conductive metal particles, especially metal nanoparticles. The metal nanoparticles may have various shapes and sizes, provided that the largest size of the particles is from about 1 to about 100 nm, preferably 10-80 nm. The metal nanoparticles may be incorporated into a suitable polymer and solvent to form an ink. The polymer may be any of several materials suitable for preparing inks, such as an acrylic polymer, a polyurethane, an epoxy resin, a polysiloxane, a polyvinyl acetate, and a natural gum and resin, etc. The solvent may be any one or more selected from water, ethanol, methanol, propanol, isopropanol, 1-butanol, 2-butanol, isobutanol, hexanol, benzene, toluene, xylene, dimethylformamide, dimethylacetamide, γ-butyrolactone, diethyl adipate, ethylene glycol butyl ether acetate, etc. The ink may further include other additives such as a dispersant, a leveling agent, a defoamer, etc. The amount of the nano-metal particles in the ink is generally from about 1% to about 50% by weight, more preferably from about 5% to about 20% by weight. The metal particle-containing ink may be applied in multiple passes, e.g., 1-20 passes. MOD inks are known in the prior art.

One benefit of the MOD inks is that more uniform, flatter, and denser films can be formed compared to other inks (e.g., nanoparticle inks). Layers obtained from the nano-metal particle-containing inks are generally very loose, i.e., have high porosity, whereas layers obtained by using the MOD inks have much lower porosity. Unlike the nanoparticle inks, the MOD inks are solutions rather than mixtures (suspensions), which do not precipitate over time and cause fewer problems during application (e.g., less likely to clog nozzles). The viscosity of the MOD inks can be easily adjusted to adjust jetting properties and adjust annealing temperatures. Additionally, the MOD inks are environmentally friendly, comprise no nanoparticles, are more readily available, and can ultimately be less expensive than nanoparticle inks.

The MOD ink used in the present invention comprises the following components: a) at least one metal precursor; and b) a solvent.

The metal in the MOD ink includes, but is not limited to, Ag, Cu, Pt, Au, and/or Sn.

The metal precursor has a decomposition temperature of 80-500° C., such as 80-500° C., or 150-500° C., or 180-350° C., or 150-300° C., or 180-270° C.

The metal precursor comprises, preferably consists of, the following components:
a) at least one metal cation; and
b) at least one anion selected from a carboxylate radical, a carbamate radical, a nitrate radical, a halide ion, and an oxime.

A combination of two or more metal precursors may be used. The two or more metal precursors have the same metal cation but have the same or different types of anions; or have different metal cations but have the same type of anion. For example, this includes a combination of a silver carboxylate and a tin carboxylate, a combination of two different silver carboxylates, and a combination of a silver carboxylate and silver carbamate, etc.

Carboxylate salts are salts consisting of one or more metal cations and one or more carboxylate anions. The carboxylic acid moiety of the carboxylate anion may be linear or branched, or have cyclic structural units, and may be saturated or unsaturated. Further preferred types of carboxylate salts are mono-carboxylate salts and di-carboxylate salts, or cyclic carboxylate salts. In one embodiment, linear saturated carboxylate salts are preferred, such as carboxylate salts having 1-20 carbon atoms. Such linear carboxylate salts may be selected from acetate salts, propionate salts, butyrate salts, valerate salts, caproate salts, heptanoate salts, caprylate salts, nonanoate salts, decanoate salts, undecanoate salts, dodecanoate salts, myristate salts, hexadecanoate salts, or octadecanoate salts. In another embodiment, saturated isocarboxylates and saturated neocarboxylates having 1-20 carbon atoms may be used. In one embodiment, saturated neocarboxylates having five or more carbon atoms are preferred, e.g., neopentanoate salts, neohexanoate salts, neoheptanoate salts, neooctoate salts, neononanoate salts, neodecanoate salts, and neododecanoate salts.

The halide ion is selected from a fluoride ion, a chloride ion, a bromide ion, and an iodide ion.

The metal content in the MOD ink is from about 1% to about 60% by weight calculated according to the metal, for example, from about 1% to about 50% by weight or from about 10% to about 40% by weight, based on the total weight of the MOD ink, which is typically measured by thermogravimetric analysis (TGA) assay.

The MOD ink further comprises a solvent. The MOD ink comprises from about 0.1% to about 90% by weight, preferably from about 20% to about 90% by weight of a solvent, in each case based on the total weight of the MOD ink.

As the solvent, a solvent selected from diol ethers, terpenes, aliphatic hydrocarbons, aromatic hydrocarbons, ketones, aldehydes, or combinations thereof may be used.

The diol ethers are organic substances having at least one diol unit. As the diol ethers, ethylene glycol ethers, diethylene glycol ethers, triethylene glycol ethers, tetraethylene glycol ethers, propylene glycol ethers, dipropylene glycol ethers, etc. may be mentioned. Commercially available examples are DOWANOL PNP (propylene glycol n-propyl ether) and DOWANOL PNB (propylene glycol n-butyl ether), DOWANOL DPNB (dipropylene glycol n-butyl ether), and DOWANOL DPNP (dipropylene glycol n-propyl ether).

The terpenes are naturally existing unsaturated hydrocarbons that can be separated from natural substances and structures thereof can be derived from one or more isoprene units. Some terpenes are also available industrially and artificially. The terpenes are preferably acyclic terpenes or cyclic terpenes. Among the cyclic terpenes, monocyclic terpenes are preferred. Preferably, the terpenes are selected from orange terpene, limonene, and pinene, or combinations thereof.

Other suitable solvents such as aliphatic hydrocarbons, aromatic hydrocarbons, ketones, and aldehydes are known in the art.

The MOD ink may optionally comprise one or more other components such as an adhesion promoter, a viscosity aid agent and other additives.

In one embodiment, the MOD ink may comprise an adhesion promoter, preferably, the adhesion promoter may be present in an amount ranging from about 0.1% to about 5% by weight, based on the total weight of the MOD ink.

In one embodiment, the MOD ink may comprise one or more viscosity aid agents in a weight proportion of about 5% to about 30% by weight, more preferably about 10% to about 20% by weight, based on the total weight of the ink.

Rosin resins or derivatives thereof are suitable viscosity aid agents for inks, such as balsam resins, cyanate esters, etc.

In one embodiment, the MOD ink may comprise other additives in proportions of from about 0.05% to about 3% by weight, more preferably from about 0.05% to about 1% by weight, in each case based on the total weight of the ink. All chemicals known to those skilled in the art that are suitable as ink additives may be used as the other additives, such as dispersants, leveling agents, defoamers, etc. Silicone-containing additives such as polyether-modified polydimethylsiloxanes are particularly preferred.

In one embodiment, the content of metal particles in the MOD ink is less than 1% by weight, or less than 0.5% by weight, or less than 0.2% by weight, based on the total weight of the MOD ink. Most preferably, the composition of the present invention is substantially free of metal particles.

The MOD ink may have a viscosity suitable for application, e.g., the ink has a viscosity of about 0.1 to about 100 mPa·s, e.g., about 5 to about 30 mPa·s, measured at a temperature of 20° C. and an ambient pressure of 1013 hPa.

The components in the MOD ink may be mixed in all manners known to those skilled in the art and considered appropriate. The mixing may be performed at a slightly elevated temperature to facilitate the mixing process. Typically, the temperature during the mixing does not exceed 40° C. The ink may be stored at room temperature, or in a refrigerator.

The metal particle-containing ink and the MOD ink may be applied on the primer layer precursor by spray coating, spin coating, dip coating, dispensing, slot coating, or printing, preferably by screen printing or inkjet printing, more preferably by inkjet printing. The MOD ink may be applied in multiple passes, e.g., 1-20 passes.

The metal conductive layer of the present invention may be applied in a conformal or patterned manner.

When the conductive layer precursor is provided in both forms of metal particle-containing ink and the MOD ink, the metal in the metal particle-containing ink may be the same as or different from the metal in the MOD ink. When the metal in the metal particle-containing ink is different from the metal in the MOD ink, preferably, the metal in the metal particle-containing ink and the metal in the MOD ink are capable of forming an alloy, such as silver and tin.

### Hybrid Layer

The metal conductive layer precursor may be provided in the form of a MOD ink, or may be provided in both forms of a metal particle-containing ink and a MOD ink. When the metal conductive layer precursor is provided in both forms of the metal particle-containing ink and the MOD ink, the portion of the metal conductive layer precursor that is immediately adjacent to the primer layer is provided in the form of the MOD ink. During formation of the printed product of the present invention, the primer layer precursor is applied on the substrate first, and the MOD ink is applied while the primer layer precursor is not fully cured (“wet-on-wet”), and is then cured with the primer layer precursor in the same curing process. In this way, a hybrid layer is formed between the metal conductive layer and the primer layer, wherein the hybrid layer comprises materials from the primer layer and the metal conductive layer. The inventors consider that the mechanism for the formation of such a hybrid layer lies in the interpenetration/invasion of the uncured MOD ink and the incompletely cured layer precursor near the interface therebetween. It is worth noting that the purpose of the above determination on the formation mechanism of the hybrid layer is to help readers understand the structure of the hybrid layer of the present invention, and should not be construed as a limitation to the scope of protection of the present application.

The thickness of the hybrid layer may be 200-2000 nm, preferably 250-1500 nm, more preferably 300-1000 nm. In the hybrid layer, the material from the metal conductive layer has a gradient distribution in the hybrid layer. In this context, the “gradient distribution” means that there is a gradient in the distribution of the material from the metal conductive layer in the hybrid layer. For example, the “gradient distribution” may be in terms of metal content or in terms of crystal granularity and dimension. For example, in the direction from the primer layer to the conductive layer, the content of the material from the metal conductive layer, especially the metal, gradually increases, and/or the material from the metal conductive layer, especially the metal, gradually increases in granularity and gradually merges, until a complete layer is formed at the metal conductive layer, and/or the metal particle size gradually increases.

The presence of the hybrid layer ensures interlocking connection of the metal conductive layer and the primer layer, and thus the presence of the hybrid layer significantly improves the adhesion/peel resistance compared to a metal layer alone. Therefore, when a metallized layer is fabricated in this way, requirements for ink adhesion are relatively low, which expands the design space of people when designing a metallized layer process. In other words, for the same metallized layer, this technical solution can reduce time and capital costs of developing new inks.

Compared with the prior art method of applying a metal nanoparticle-containing ink in a “wet-on-wet” manner to a primer layer precursor that has not been fully cured, the method of applying the MOD ink to the primer layer precursor that has not been fully cured in a “wet-on-wet” manner of the present invention has the following unexpected and advantageous technical effects:
(1) Since the MOD ink is in a liquid form and has good fluidity, the MOD compound therein can invade deeper into the primer layer precursor, thereby forming a thicker hybrid layer and thus having better adhesion. On the contrary, when the metal nanoparticle-containing ink in the prior art is used, due to the high viscosity of the ink and the poor fluidity of the nanoparticles, the migration of the metal nanoparticles into the primer layer precursor substantially cannot occur, but mainly a resin component in the primer layer is mixed with a resin component in the metal nanoparticle-containing ink, and therefore the thickness of the formed hybrid layer is very small, and the improvement effects on adhesion are very limited.
(2) When the metal nanoparticle-containing ink in the prior art is used, high temperature sintering is required in subsequent operations, which is usually very time-consuming and leads to high costs; whereas when the MOD ink is used, high temperature sintering is not required, which saves time and capital costs.
(3) When the metal nanoparticle-containing ink in the prior art is used, the contact between the metal particles after high temperature sintering is poor. Especially in the field of electronics, when a lower sintering temperature and shorter sintering time are adopted in order to take into account the performance limits of high temperature resistance of electronic products, the contact between the metal particles after sintering of the metal nanoparticle-containing ink is very poor; whereas when the MOD ink is used, the contact between the obtained metal particles is very good even without a high temperature process, thus improving the conductivity.
(4) Typically, in the case of a planar EMI shielding layer, in order to obtain a better shielding effect, it is generally required that there should be no through-hole/micro-gap in a metal layer. Furthermore, from the perspective of control of the volume, weight, and costs of electronic products, the thickness of the metal layer is generally required to be small. For linear EMI, metal lines are generally required to be tall and thin based on requirements for resistivity and circuit board area. The metal nanoparticle-containing ink in the prior art has a high viscosity and is suitable for fabricating a linear EMI structure. However, during fabrication of a planar EMI structure, in order to obtain a better shielding effect, it is often necessary to fabricate a metal layer with a larger thickness, which leads to an increase in the costs and weight of an EMI shielding layer. On the contrary, when the MOD ink is used, due to the lower viscosity and better uniformity and fluidity thereof, a uniform and dense metal layer with a small thickness can be formed, which is therefore suitable for forming planar EMI with good shielding effects, such as EMI in 5G applications, especially suitable for weight-sensitive apparatuses, such as mobile smart apparatuses, flight vehicles, wearable apparatuses, etc.
(5) It is generally believed that when a MOD ink in a liquid form is applied to a primer layer precursor in the form of slurry that is not fully cured, the liquid surface will be broken due to the action of surface tension, and consequently a continuous liquid film cannot be formed. Surprisingly, however, it is found that a continuous liquid film is formed when the MOD ink is applied using inkjet printing in a “wet-on-wet” manner on a primer layer precursor that has not been fully cured. This overcomes existing technical biases.

### Other Layers

Other layers, such as a thermal interface material layer and a protective layer, may be applied on the printed product of the present invention.

The protective layer can protect the printed product of the present invention from physical abrasion, moisture effects, and oxidation and coordination reactions. Suitable protective layer materials are epoxy resins, phenolic resins, polyurethane resins, etc.

The other layers may be applied by spray coating, spin coating, dip coating, dispensing, slot coating, or printing, preferably by screen printing or inkjet printing, more preferably by inkjet printing.

The other layers may be applied in a conformal or patterned manner. When the protective layer is selectively printed, a desired good thermal conduction channel can be obtained, and at the same time, a good protective effect can be obtained.

### Preparation Method for the Printed Product of the Present Invention

In a second aspect, the present invention relates to a method for manufacturing a printed product, including:
1) providing a substrate;
2) applying a primer layer precursor on the substrate;
3) in a first cycle, applying a MOD ink sublayer on the primer layer precursor while the primer layer precursor is not fully cured;
4) co-curing the layers obtained from steps 2) and 3);
5) optionally, in one or more subsequent cycles, applying one or more other ink sublayers and curing the ink sublayer; and
6) annealing a resulting product.

The metal conductive layer precursor (i.e., the ink) comprises metal particles or at least one MOD compound, preferably at least one MOD compound.

The primer layer precursor and the metal conductive layer precursor may be applied in a conformal or patterned manner, and may be applied using a suitable method, such as by spray coating, spin coating, dip coating, dispensing, slot coating, or printing, preferably by screen printing or inkjet printing, more preferably by inkjet printing.

The inkjet printing is an additive manufacturing process that reduces material waste and requires no masking or etching steps. Furthermore, the inkjet printing can process larger chips (e.g., 300 mm chips), which reduces the need for expensive metal deposition equipment for such chips, and in turn reduces manufacturing costs.

The inkjet printing may be performed in a patterned manner. The inkjet printing may be performed using any type of inkjet printer, such as a piezoelectric inkjet printer. The number of layers applied by inkjet printing may be one or more layers in order to obtain a desired layer thickness, preferably 1-10 layers. The layer thickness of inkjet printing may be adjusted by adjusting the printing resolution and the number of layers. The DPI range X/Y for inkjet printing may be 300-3000. In the case of applying the primer layer precursor by inkjet printing, after the end of the application, the primer layer precursor may be leveled for 1-15 minutes, preferably 1-5 minutes, so as to better spread the primer layer precursor on the substrate.

In one embodiment, the primer layer precursor may be simultaneously printed using one or more inkjet printing apparatuses at a certain angle (e.g., 1-90°, preferably 10-70°, more preferably 20-50°, particularly 45°) relative to the normal to the surface of the substrate (e.g., a PCB), such that the primer layer precursor can at least partially fill the grooves on the surface of the substrate, thereby reducing the waviness or roughness of the substrate surface, so as to planarize the surface of the substrate, thereby reducing the aspect ratio between parts in PCBA applications, reducing the shadow area, and increasing the coverage of the subsequent conductive layer, and additionally planarizing the surface with roughness, thereby achieving a better thickness and shielding uniformity.

As described above, the metal conductive layer precursor may be provided in the form of a MOD ink; or may be provided in both forms of a metal particle-containing ink and a MOD ink. When the metal conductive layer precursor is provided in both forms of the metal particle-containing ink and the MOD ink, the portion of the metal conductive layer precursor that is immediately adjacent to the primer layer is provided in the form of the MOD ink. The MOD ink is applied while the primer layer precursor is not fully cured, i.e., a “wet-on-wet” method. By means of the “wet-on-wet” method, the metal precursor in the MOD ink invades into the primer layer, forming a gradient region between the metal conductive layer and the primer layer, thereby ensuring interlocking connection of the metal conductive layer and the primer layer, which is more reliable than connection of the conductive layer on a flat primer layer.

In the first cycle, a MOD ink sublayer is applied on the primer layer precursor in a “wet-on-wet” manner; the MOD ink sublayer and the primer layer precursor are co-cured; and optionally, in one or more subsequent cycles, one or more other ink sublayers are applied and cured on the MOD ink sublayer.

The other ink sublayer may be a MOD ink sublayer or a metal particle-containing ink sublayer, wherein the metal in the metal particle-containing ink is the same as or different from the metal in the MOD ink. When the metal in the metal particle-containing ink is different from the metal in the MOD ink, the metal in the metal particle-containing ink and the metal in the MOD ink are capable of forming an alloy, such as silver and tin.

In the “subsequent cycle or cycles” described above, a pass of the MOD ink or the metal particle-containing ink may be applied. Specific application conditions may be determined according to many factors such as speed requirements, costs, thickness requirements, and the like. For example, the MOD ink may be applied throughout all the cycles. As another example, the MOD ink is applied in the first cycle and the metal particle-containing ink is applied in subsequent cycles. As another example, the MOD ink is applied in the first three cycles and the metal particle-containing ink is applied in subsequent cycles. As still another example, the MOD ink is applied in the first, third, and fifth cycles and the metal particle-containing ink is applied in the second, fourth, and sixth cycles.

In each cycle, the applied MOD ink layer or metal particle-containing ink may have a thickness of 100-400 nm, more preferably 200-300 nm. In some cases, applying an overly thick ink layer at one time may cause problems with the uniformity, robustness, and peel resistance of the resulting metal conductive layer, whereas by applying the MOD ink and/or the metal particle-containing ink in multiple passes, the layer thickness can be well controlled, so as to obtain a metal conductive layer with good uniformity, robustness, and peeling resistance. The number of cycles may be 1-20, preferably 2-10, more preferably 3-8, for example, 3-5.

In the case of applying the MOD ink and/or the metal particle-containing ink in multiple cycles, after the first pass of the MOD ink is applied, the first pass of the MOD ink is cured together with the primer layer precursor, and then after each pass of the MOD ink or the metal particle-containing ink is applied, the pass of the MOD ink or the metal particle-containing ink is cured.

The curing may be performed by heating and/or electromagnetic radiation. In one embodiment of the present invention, heating and electromagnetic radiation may be performed simultaneously; or heating followed by electromagnetic radiation; or electromagnetic radiation followed by heating. Electromagnetic radiation curing includes, for example, UV, IR, and electron beam curing, etc., preferably UV curing.

When curing is performed by heating, the curing can be performed in an oven. The heating temperature may be from about 50 to about 250° C., preferably from about 80 to about 200° C., more preferably from about 150 to about 200° C., and the heating time may be from about 1 to about 60 minutes, preferably from about 5 to about 40 minutes.

When the curing is performed by electromagnetic radiation, electromagnetic radiation having a wavelength of from about 100 nm to about 1 mm, preferably from about 100 to about 2000 nm, more preferably from about 100 to about 800 nm may be used. The radiation intensity may be from about 100 to about 1,000 W/cm², preferably from about 100 to about 500 W/cm², more preferably from about 100 to about 400 W/cm². The radiation rate may be from about 0.01 to about 1000 mm/s, preferably from about 0.1 to about 500 mm/s, more preferably from about 0.1 to about 50 mm/s. The irradiation may be carried out for 1-100 passes, preferably 1-50 passes. The method of the present invention may further include step 6), i.e., annealing the product obtained in step 4) or 5).

The annealing temperature is related to the melting point of the metal, and for metals with higher melting points, higher annealing temperatures may be used. The annealing temperature may be from about 100 to about 600° C., preferably from about 150 to about 500° C. The annealing time is also related to the melting point of the metal, and for metals with higher melting points, longer annealing time may be used. The annealing time may be from about 1 to about 60 minutes, preferably from about 5 to about 40 minutes, and more preferably from about 5 to about 30 minutes.

The annealing may be performed in air if the metal in the ink used is not easily oxidized. Certainly, the annealing may also be performed in an inert atmosphere. Examples of inert atmospheres include, but are not limited to, nitrogen, helium, argon, neon, etc.

The annealing may be performed in any suitable apparatus, for example in a tube furnace.

The method of the present invention may further include other steps, such as a step of performing surface preprocessing on the substrate prior to step 1).

As surface preprocessing methods, UV, ozone, plasma, corona, etc. may be mentioned.

The plasma processing may include vacuum plasma processing and air-conditioned plasma processing. The time for the plasma processing may be from about 1 to about 60 minutes, preferably from about 1 to about 10 minutes.

By the surface preprocessing, the cleanliness of the substrate surface can be improved and the surface of the substrate can be activated. Applicants have surprisingly found that good wetting of the subsequently applied primer layer precursor, especially an epoxy primer composition, can be ensured when the surface energy is at least 40 mN/m. The surface energy is obtained by measuring a contact angle using polar and non-polar liquids.

After cleaning processing, the substrate may be heated, for example to a temperature of 25-90° C., preferably 30-45° C. In this way, better spreading of the subsequently applied primer layer precursor on the substrate can be ensured.

The primer layer precursor is preferably applied within 5 minutes after the cleaning processing to prevent the cleaned surface from absorbing particulate matter and the surface energy from decreasing over time.

Therefore, in a preferred embodiment, the present invention relates to a method for manufacturing a printed product, including:
1) providing a substrate;
2) performing surface preprocessing on the substrate;
3) applying a primer layer precursor on the preprocessed substrate;
4) in a first cycle, applying a MOD ink sublayer on the primer layer precursor while the primer layer precursor is not fully cured;
5) co-curing the layers obtained from steps 3) and 4);
6) optionally, in one or more subsequent cycles, applying one or more other ink sublayers and curing the ink sublayer; and
7) annealing a resulting product.

In one embodiment of the present invention, the present invention relates to a method for manufacturing a printed product, wherein the method includes the steps of:
1) providing the substrate with the grooves on the surface;
2) applying the primer layer precursor in the grooves to partially or completely fill the grooves; and optionally, applying the primer layer precursor on other portions of the substrate surface;
3) in a first cycle, applying a MOD ink sublayer on the primer layer precursor while the primer layer precursor is not fully cured;
4) co-curing the layers obtained from steps 2) and 3);
5) optionally, in one or more subsequent cycles, applying one or more other ink sublayers and curing the ink sublayer; and
6) annealing a resulting product.

Other layers such as a thermal interface material layer and a protective layer may be further provided on the substrate with the conductive layer.

The primer layer precursor and the metal conductive layer precursor (i.e., the ink) may be applied in a patterned or conformal manner, preferably in a patterned form, i.e., covering a selected region of the substrate with the primer layer precursor, while other regions remain uncovered with the primer layer precursor, at least partially applying the metal conductive layer precursor on the covered and uncovered regions, wherein a hybrid layer is formed between the primer layer and the metal conductive layer, wherein regions containing no primer layer are optionally attached to a thermal interface material, wherein the selected region includes a plurality of devices.

The method of the present invention can be utilized to obtain a PCBA (for example, an FPCB), an EMI shielding element, an antenna, a capacitive touch sensor, a conductive wire, a high frequency apparatus such as a 5G apparatus, a ceramic filter element, or a drone, etc.

### Electronic Device

In another aspect, the present invention relates to an electronic device including the above printed product.

The printed product of the present invention or the printed product obtainable by the method of the present invention has very good EMI shielding performance and high thermal conductivity, and is therefore suitable for use in various electronic devices.

The electronic device may be a PCBA (for example, an FPCB), an EMI shielding element, an antenna, a capacitive touch sensor, a conductive wire, a high frequency apparatus such as a 5G apparatus, a ceramic filter element, or a drone, etc.

### Advantages of the Present Invention

The advantages of the present invention reside in one or a combination of more of the following:
1) In a preferred embodiment of the present invention, an inkjet printing method is used to deposit the primer layer precursor, which helps to planarize the surface of the substrate, which can reduce the aspect ratio between parts in PCBA applications, reduce the shadow area, improve the coverage of the subsequent conductive layer, so as to achieve a better thickness and shielding uniformity.
2) The presence of the hybrid layer improves the adhesion between the primer layer and the conductive layer, and is easy to implement, thereby making the present invention suitable for various conductive coatings that require good adhesion; the process is simpler to implement, and the same apparatus can carry out application of the metal conductive layer; the adhesion is not easily affected by other factors, thereby achieving higher reliability; by selecting the materials of the metal conductive layer so that the CTE coefficients thereof are similar, making it possible to better improve the operating durability of the apparatus in high and low temperature shock environments.
3) The method of the present invention is easy to implement, and can be easily scaled up to large-scale industrial production.
4) The EMI shielding effect of the printed product of the present invention is good, making it possible to use the printed product in high frequency applications such as 5G applications.

### BRIEF DESCRIPTION OF THE DRAWINGS

FIG. 1 illustrates a flow diagram of one embodiment of a method of the present invention.

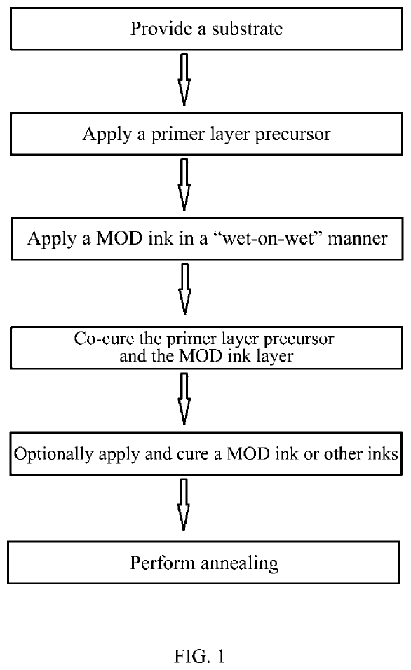

FIG. 2 shows a schematic diagram of the structure of a printed product of the present invention.

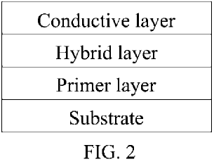

### EXAMPLES

An objective of the following examples is to further illustrate the present invention, but not to limit the scope of the present invention.

### Testing Method

### Sheet Resistivity

To measure the sheet resistivity of the layers obtained by the method of the present invention, a four-point probe from Ossila, Sheffield, UK is used.

### Peel Test

Adhesion is characterized by peel testing. The peel test standard is ASTM D3359-09.

### Example 1

1) The surface of a PCBA (BYD, CS2402-02) was cleaned with air-conditioned plasma (moving speed 20 mm/s) for 3 minutes.
2) The PCBA was placed in a 40° C. oven for 3 minutes; then within 5 minutes after the plasma cleaning, a Heraeus inkjet printer with a print head model RICOH MH5421F was used to perform inkjet printing of an epoxy coating composition (KIWOMASK IJ 7326 VP), for a total of 3 passes, each with a thickness of 200 nm; after the primer was applied, the primer was leveled for 2 minutes.
3) A Heraeus inkjet printer with a print head model RICOH MH5421F was used to perform inkjet printing of a MOD silver ink at a DPI of 1200*1600, for a total of 3 passes, each with a thickness of 200 nm; the MOD silver ink was composed of 15% by weight of silver neodecanoate and 85% by weight of limonene (DL-limonene, CAS No. 138-86-3, available from Merck KGaA, Cat. No. 814546), each based on the total weight of the ink.
4) A Heraeus UV curing apparatus Heraeus Semray 4103 was used to cure the primer layer and the silver ink layer (wavelength: 395 nm, speed: 1 mm/s, 1 pass, radiation intensity: 250 W/cm²), for 5 minutes.
5) A Heraeus inkjet printer with a print head model RICOH MH5421F was used to perform inkjet printing of a MOD silver ink at a DPI of 1200*1600, for a total of 3 passes, each with a thickness of 150 nm; the MOD silver ink was the same as that in step 3).
6) A Heraeus UV curing apparatus Heraeus Semray 4103 was used to cure the MOD silver ink (wavelength: 395 nm, speed: 1 mm/s, 1 pass, radiation intensity: 250 W/cm²) for 5 minutes.
7) An SG-XL1200 annealing apparatus (Ansheng Electric Furnace) was used to perform annealing at 150° C. for 20 minutes.

### Comparative Example 1

The steps of Example 1 was repeated except that the step of applying the MOD ink composition of step 3) was omitted, but the curing of step 4) was still carried out. The adhesion and sheet resistivity of the obtained PCBA were measured, and the results are shown in Table 1:

TABLE 1
Adhesion and sheet resistivity of
Example 1 and Comparative Example 1

| | Adhesion | Sheet Resistivity (mohm/sq) |
|---|---|---|
| Comparative Example 1 | 0B (fail) | 30 |
| Example 1 | 5B (pass) | 33 |

As can be seen from Table 1, by forming a hybrid layer between the primer layer and the conductive layer, the adhesion of the EMI shielding element was greatly improved, and the sheet resistivity was also improved.

A FIB study was carried out on the cross section of the surface of the plastic package in Example 1, and the results showed that the conductive layer had a dense structure with less porosity, and the hybrid layer was formed between the primer layer and the metal conductive layer, and the thickness thereof was 910 nm. Ag had a gradient distribution in the hybrid layer, that is, in the direction from the primer layer to the conductive layer, the Ag content gradually increased, and the Ag particles gradually increased in size and merged until a complete conductive layer was formed at the conductive layer. The presence of the hybrid layer ensured the sheet resistivity and effectively improved the adhesion of the shielding layer.

1. A printed product, comprising:
a. a substrate;
b. a primer layer located on the substrate, wherein the primer layer comprises an organic dielectric material; and
c. a metal conductive layer located on the primer layer;
wherein the printed product further comprises a hybrid layer between the primer layer and the metal conductive layer, wherein the hybrid layer comprises materials from the primer layer and the metal conductive layer.

2. The printed product according to claim 1, wherein the material from the metal conductive layer has a gradient distribution in the hybrid layer.

3. The printed product according to claim 2, wherein the gradient is one or more selected from the group consisting of a content gradient, a granularity gradient, and a crystal size gradient.

4. The printed product according to claim 1, wherein a thickness of the hybrid layer is 200-2000 nm, preferably 250-1500 nm, and more preferably 300-1000 nm.

5. The printed product according to claim 1, wherein the metal conductive layer comprises a metal selected from Ag, Cu, Pt, Au, and Sn, or a combination thereof.

6. The printed product according to claim 1, wherein a metal conductive layer precursor is provided in the form of a MOD ink; or provided in both forms of a metal particle-containing ink and the MOD ink, provided that the portion of the metal conductive layer precursor that is immediately adjacent to the primer layer is provided in the form of the MOD ink.

7. The printed product according to claim 5, wherein when the metal conductive layer precursor is provided in both forms of the metal particle-containing ink and the MOD ink, a metal in the metal particle-containing ink is the same as or different from a metal in the MOD ink, wherein when the metal in the metal particle-containing ink is different from the metal in the MOD ink, the metal in the metal particle-containing ink and the metal in the MOD ink are able to form an alloy, such as silver and tin.

8. The printed product according to claim 1, wherein the substrate has a surface and the surface comprises at least one material selected from a polymer, a metal, ceramic, and glass, or a mixture thereof (for example, an epoxy molding compound).

9. The printed product according to claim 1, wherein the substrate has grooves on the surface, and the grooves are partially or completely filled with the primer layer.

10. The printed product according to claim 1, wherein the printed product comprises a heat generating device, wherein a thickness of the primer layer on the heat generating device is less than a thickness of the primer layer on at least a portion of other regions.

11. The printed product according to claim 1, wherein the entire surface or a selected region of the surface of the substrate is covered with the primer layer, wherein the covered region comprises the primer layer, the hybrid layer, and the metal conductive layer, wherein the selected region comprises a plurality of devices.

12. The printed product according to claim 1, wherein the substrate is any element requiring metallization, or an element requiring EMI shielding.

13. The printed product according to claim 1, wherein a waviness or roughness of the surface of the substrate is higher than a waviness or roughness of the surface of the primer layer.

14. The printed product according to claim 1, which is a PCBA such as an FPCB.

15. A method for manufacturing the printed product according to claim 1, comprising:
1) providing a substrate;
2) applying a primer layer precursor on the substrate;
3) in a first cycle, applying a MOD ink sublayer on the primer layer precursor while the primer layer precursor is not fully cured;
4) co-curing the layers obtained from steps 2) and 3);
5) optionally, in one or more subsequent cycles, applying and curing one or more other ink sublayers; and
6) annealing a resulting product.

16. The method according to claim 15, wherein the printed product comprises a heat generating device, wherein a thickness of the primer layer on the heat generating device is less than a thickness of the primer layer on at least a portion of other regions.

17. The method according to claim 15, wherein the primer layer precursor, the MOD ink sublayer, and the other ink sublayers are applied by spray coating, spin coating, dip coating, dispensing, slot coating, or printing, preferably by screen printing or inkjet printing, and more preferably by inkjet printing.

18. The method according to claim 15, wherein the primer layer precursor and/or the MOD ink sublayer and/or the other ink sublayers are applied in a conformal or patterned manner.

19. The method according to claim 18, wherein the other ink sublayers are a MOD ink sublayer or a metal particle-containing ink sublayer.

20. The method according to claim 19, wherein a metal in the metal particle-containing ink is the same as or different from a metal in the MOD ink, wherein when the metal in the metal particle-containing ink is different from the metal in the MOD ink, the metal in the metal particle-containing ink and the metal in the MOD ink are able to form an alloy, such as silver and tin.

21. The method according to claim 15, wherein the substrate is a substrate having grooves on the surface, and the method comprises the steps of:
1) providing a substrate with grooves on the surface;
2) applying a primer layer precursor in the grooves to partially or completely fill the grooves; and optionally, applying the primer layer precursor on other portions of the surface of the substrate;
3) in a first cycle, applying a MOD ink sublayer on the primer layer precursor while the primer layer precursor is not fully cured;
4) co-curing the layers obtained from steps 2) and 3);
5) optionally, in one or more subsequent cycles, applying and curing one or more other ink sublayers; and
6) annealing a resulting product.

22. An electronic device, comprising the printed product according to claim 1.

23. The electronic device according to claim 22, which is a PCBA (for example, an FPCB), an EMI shielding element, an antenna, a capacitive touch sensor, a conductive wire, a high frequency apparatus such as a 5G apparatus, a ceramic filter element, or a drone.
